(19) United States
(12) Patent Application Publication
(10) Pub. No.: US 2016/0041441 A1
(43) Pub. Date: Feb. 11, 2016

(54) DISPLAY PANEL AND METHOD FOR MANUFACTURING THE SAME

(71) Applicant: Samsung Display Co., Ltd., Yongin-City (KR)

(72) Inventors: Je-Hyeong PARK, Seoul (KR); Swae-Hyun KIM, Asan-si (KR); Do-Yeong PARK, Seoul (KR); Chang-Il TAE, Seoul (KR)

(21) Appl. No.: 14/681,380

(22) Filed: Apr. 8, 2015

(30) Foreign Application Priority Data
Aug. 8, 2014 (KR) 10-2014-0102504

(51) Int. Cl. G02F 1/1362; G02F 1/1368; G02F 1/1339; H01L 27/12

(52) U.S. Cl. CPC G02F 1/136209; H01L 27/124; H01L 27/1248; H01L 27/1262; G02F 1/136286; G02F 1/1368; G02F 1/13394

(57) ABSTRACT

A display panel includes a first substrate, a second substrate, a thin film transistor, a black column spacer and a barrier layer. The first substrate includes a gate line extending in a first direction and a data line extending in a second direction crossing the first direction. The second substrate faces the first substrate. The thin film transistor is disposed on the first substrate, and connected to the gate line and the data line. The black column spacer includes a blocking part covering the gate line and the thin film transistor, and a maintaining part integrated with the blocking part. The maintaining part maintains a cell gap between the first substrate and the second substrate. The maintaining part includes a material substantially the same as that of the blocking part. The barrier layer covers the blocking part.

### CLAIM OF PRIORITY

This application makes reference to, incorporates the same herein, and claims all benefits accruing under 35 U.S.C §119 from an application earlier filed in the Korean Intellectual Property Office on the 8^{th} of August 2014 and there duly assigned Serial No. 10-2014-0102504.

### BACKGROUND OF THE INVENTION

1. Field of the Invention

Exemplary embodiments of the inventive concept relate to a display panel and a method for manufacturing the same. More particularly, exemplary embodiments of the inventive concept relate to a display panel improved reliability and a method for manufacturing the display panel.

2. Description of the Related Art

A liquid crystal display apparatus is one of a flat panel display FPD, which is used broadly recently. Examples of the flat panel display include, but are not limited to, a liquid crystal display (“LCD”), a plasma display panel (“PDP”) and an organic light emitting display (“OLED”).

The liquid crystal display apparatus applies voltages to molecules of liquid crystal to adjust arrangements of the molecules thereby changing optical characteristics of a liquid crystal cell such as birefringence, optical activity, dichroism and light scattering to display an image.

The liquid crystal display apparatus includes a liquid crystal display panel displaying an image and a backlight unit providing light to the liquid crystal display panel. The liquid crystal display panel includes a metal line formed by a metal, which reflects light. A black matrix is formed on the metal line to prevent light from providing to the metal line. Generally, the liquid crystal panel includes two substrates, and a column spacer is formed to maintain a cell gap between the substrates.

Recently, a black column spacer is used broadly. The black column spacer includes the black matrix and the column spacer, and the black matrix and the column spacer are formed at the same time.

However, when the black column spacer is in contact with a liquid crystal layer, a component of the black column spacer is spread out to the liquid crystal layer, thus an afterimage may be occur on a screen.

Furthermore, an alignment layer aligning liquid crystal molecules is formed on the black column spacer, properties of the alignment layer and the black column spacer are different, so that a lump of the alignment layer may occur.

### SUMMARY OF THE INVENTION

Exemplary embodiments of the inventive concept provide a display panel improved an afterimage, and forming a uniform alignment layer.

Exemplary embodiments of the inventive concept also provide a method for manufacturing a display panel.

According to an exemplary embodiment, a display panel includes a first substrate, a second substrate, a thin film transistor, a black column spacer and a barrier layer.

The first substrate includes a gate line extending in a first direction and a data line extending in a second direction crossing the first direction. The second substrate faces the first substrate. The thin film transistor is disposed on the first substrate, and the thin film transistor is connected to the gate line and the data line. The black column spacer includes a blocking part covering the gate line and the thin film transistor, and a maintaining part integrated with the blocking part. The maintaining part maintains a cell gap between the first substrate and the second substrate. The maintaining part includes a material substantially the same as that of the blocking part. The barrier layer covers the blocking part.

In an exemplary embodiment, the barrier layer may include silicon nitride (SiNx) or silicon oxide (SiOx).

In an exemplary embodiment, the barrier layer may include chromium (Cr).

In an exemplary embodiment, the maintaining part may have a height of about 0.5 μm to about 3.0 μm.

In an exemplary embodiment, a blocking electrode may overlap with the data line.

In an exemplary embodiment, a black matrix may overlap with the data line.

In an exemplary embodiment, the black matrix may include a material substantially the same as that of the black column spacer.

In an exemplary embodiment, the barrier layer may further cover the black matrix.

In an exemplary embodiment, an alignment layer may be disposed on the first substrate and the second substrate.

In an exemplary embodiment, a liquid crystal layer may be disposed between the first substrate and the second substrate.

In accordance with an exemplary embodiment, a method for manufacturing a display panel is provided. According to the method, a thin film transistor is formed on a first substrate. The first substrate includes a gate line extending in a first direction and a data line extending in a second direction crossing the first direction. The thin film transistor is connected to the gate line and the data line. A black column spacer is formed on the first substrate. The black column spacer includes a blocking part covering the gate line and the thin film transistor and a maintaining part integrated with the blocking part. The maintaining part includes a material substantially the same as that of the blocking part. A barrier material is deposited on the first substrate to form a barrier layer. The barrier layer covers the blocking part of the black column spacer.

In an exemplary embodiment, an alignment layer may be formed on the first substrate.

In an exemplary embodiment, the barrier material may include silicon nitride (SiNx) or silicon oxide (SiOx).

In an exemplary embodiment, the barrier material may include chromium (Cr).

In an exemplary embodiment, the barrier material may be deposited on one surface of the first substrate. A portion of the barrier material may be exposed, using a mask to pattern the barrier layer.

In an exemplary embodiment, a color filter photoresist may be coated on the thin film transistor to form a color filter. A pixel electrode may be formed on the color filter.

In an exemplary embodiment, a blocking electrode may be formed. The blocking electrode may overlap with the data line.

In an exemplary embodiment, a black matrix may be formed. The black matrix may overlap with the data line.

In an exemplary embodiment, a black photoresist may be coated on the first substrate. A first light may be irradiated to the black photoresist. The black column spacer may be developed. A second light may be irradiated to the blackphotoresist, an amount of the second light may be smaller than an amount of the first light. The black photoresist may be dried by heating.

In an exemplary embodiment, the black photoresist may include a first initiator and a second initiator. The first initiator may have a first maximum energy absorption wavelength reacting with a wavelength of the first light. The second initiator may have a second maximum energy absorption wavelength reacting with a wavelength of the second light.

In such embodiments, a contact between a black column spacer and a liquid crystal layer may be minimized so that an afterimage by the black column spacer may be improved. Furthermore, an alignment layer on the black column spacer may have a uniform surface, thus improving a liquid crystal margin and an afterimage.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIG. 1 is a plan view illustrating an exemplary embodiment of a display panel;

FIG. 2 is a cross-sectional view illustrating an exemplary embodiment of a display panel;

FIG. 3 is a cross-sectional view illustrating an exemplary embodiment of a display panel taken along the line I-I′ of FIG. 1;

FIG. 4 is a cross-sectional view illustrating an exemplary embodiment of a display panel taken along the line I-I′ of FIG. 1; and

FIG. 5 is a flow chart illustrating an exemplary embodiment of a method for manufacturing a display panel.

### DETAILED DESCRIPTION OF THE INVENTION

Hereinafter, exemplary embodiments of the inventive concept will be explained in detail with reference to the accompanying drawings.

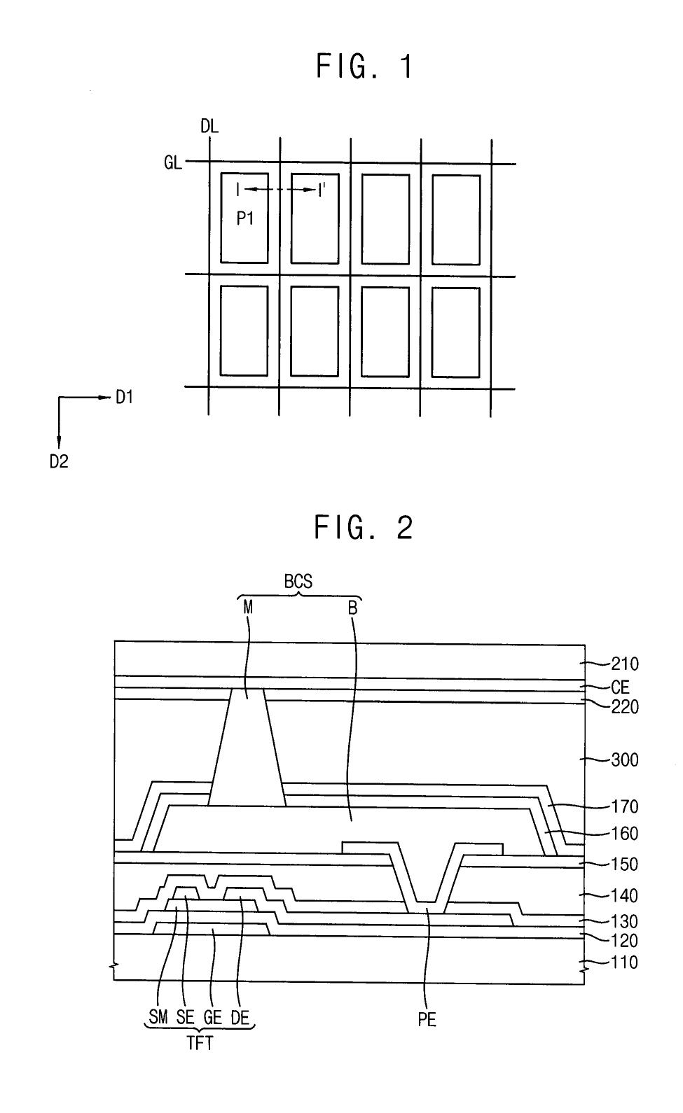

FIG. 1 is a plan view illustrating an exemplary embodiment of a display panel. FIG. 2 is a cross-sectional view illustrating an exemplary embodiment of a display panel.

Referring to FIGS. 1 and 2, the display panel includes a plurality of gate lines GL, a plurality of data lines DL and a plurality of pixels (e.g., P1).

The gate lines GL may extend in a direction D1. The data lines DL may extend in a direction D2, which is substantially crossing the direction D1. Alternatively, the gate line GL may extend in the direction D2, and the data line DL may extend in the direction D1.

The pixels may be arranged in a matrix shape. The pixels may be disposed in areas defined by the gate lines GL and the data lines DL.

Each pixel may be connected to a corresponding gate line GL and a corresponding data line DL adjacent to the pixel.

Each pixel may have a V-shape. Alternatively, the pixel may have a rectangle shape extending in a direction, a Z-shape or the like.

Referring to FIGS. 1 and 2, the display panel includes a substrate 110, a substrate 210 and a liquid crystal layer 300.

A thin film transistor TFT, a color filter 140, a pixel electrode PE and a black column spacer BCS is disposed on the substrate 110.

The substrate 110 may be a transparent insulation substrate. For example, the transparent insulation substrate may be a glass substrate, a plastic substrate or the like. The substrate 110 may include a plurality of pixel areas for displaying an image. A plurality of the pixel areas may be disposed in a matrix shape having a plurality of rows and a plurality of columns.

Each pixel may further include a switching element. For example, the switching element may be the thin film transistor TFT.

The switching element may be connected to the gate line GL and the data line DL adjacent to the switching element. The switching element may be disposed at a crossing area of the gate line GL and the data line DL.

A gate pattern may include a gate electrode GE and the gate line GL. The gate pattern may be disposed on the substrate 110. The gate line GL is electrically connected to the gate electrode GE.

A gate insulating layer 120 may be disposed on the substrate 110 to cover the gate pattern and may insulate the gate pattern.

A semiconductor pattern SM may be disposed on the gate insulating layer 120. The semiconductor pattern SM may overlap the gate electrode GE.

A data pattern may include the data line DL, a source electrode SE and a drain electrode DE. The data pattern may be disposed on the semiconductor pattern SM, which is formed on the gate insulating layer 120. The source electrode SE may overlap the semiconductor pattern SM. The source electrode SE may be electrically connected to the data line DL.

The drain electrode DE may be spaced apart from the source electrode SE on the semiconductor pattern SM. The semiconductor pattern SM may have a conductive channel between the source electrode SE and the drain electrode DE.

The TFT may include the gate electrode GE, the source electrode SE, the drain electrode DE and the semiconductor pattern SM.

The gate insulating layer 120 may be disposed on one surface of the substrate 110.

The gate insulating layer 120 may include an inorganic insulating material. For example, the gate insulating layer 120 may include silicon nitride (SiNx) or silicon oxide (SiOx).

A data insulating layer 130 may be disposed on the gate insulating layer 120 to cover the data pattern and may insulate the data pattern.

The data insulating layer 130 may be disposed on the gate line GL, the data line DL and the thin-film transistor TFT. The data insulating layer 130 may be disposed on one surface of the substrate 110.

The data insulating layer 130 may include an inorganic insulating material. For example, the data insulating layer 130 may include silicon nitride (SiNx) or silicon oxide (SiOx).

The color filter 140 may be disposed on the data insulating layer 130.

The color of light may be changed by the color filter 140 and the light may penetrate the liquid crystal layer 300. Color filters 140 may include a red color filter, green color filter and a blue color filter.

Each of the color filters 140 may correspond to one of the pixel areas. Color filters, which are adjacent to each other, may have different colors from each other.

For example, the color filters 140 may be overlapped on a border between pixel areas adjacent to each other. Alternatively, the color filters 140 may be spaced apart from a border between pixel areas adjacent to each other in the direction D1. For example, the color filters 140 may be formed in an island-shape on the data lines DL.

A passivation layer 150 may be disposed on the color filter 140.

The passivation layer 150 may include an inorganic insulating material. For example, the passivation layer 150 may include silicon nitride (SiNx) or silicon oxide (SiOx).

The pixel electrode PE may be disposed on the color filter 140 and the passivation layer 150.

The pixel electrode PE may be electrically connected to the drain electrode DE of the thin film transistor TFT through a contact hole. The pixel electrode PE may be disposed on the pixel area. A grayscale voltage may be applied to the pixel electrode PE through the thin-film transistor TFT.

For example, the pixel electrode PE may include a transparent conductive material, such as indium tin oxide (ITO), indium zinc oxide (IZO) and aluminum-doped zinc oxide (AZO). For example, the pixel electrode PE may have a slit pattern.

The black column spacer BCS may be disposed on the substrate 110 to block light.

The black column spacer BCS is formed corresponding to a non-display area.

The black column spacer BCS includes a blocking part B and a maintaining part M.

The blocking part B covers the gate line GL and the thin film transistor TFT. Thus, the blocking part B may prevent light from being proved to the gate line GL and the thin film transistor, which are formed by a reflective metal.

The blocking part B may be formed by a black material including a photosensitive organic material. For example, the black material includes a coloring agent such as a carbon black, an organic or inorganic pigment, a color mixed pigment, or the like, thus representing a black color.

The maintaining part M may be protrude from an upper surface of the blocking part B. The maintaining part M may be integrated with the blocking part B.

For example, the maintaining part M may be disposed on the thin film transistor TFT.

The maintaining part M maintains a cell gap between the substrate 110 and the substrate 210. For example, the maintaining part M may have a height of 0.5μm to about 5.0 μm. When the height of the maintaining part M is less than 0.5 μm, a liquid crystal injecting margin decreases so that a display quality of the display panel may be poor. When the height of the maintaining part M is more than 3.0 μm, the display panel may be too thick.

For example, the maintaining part M may include a material substantially the same as that of the blocking part B.

A barrier layer 160 may be disposed on an upper surface of the blocking part B of the black column spacer BCS.

The barrier layer 160 covers the blocking part B. The barrier layer 160 may prevent the black column spacer BCS from contacting with the liquid crystal layer 300.

Therefore, a component of the black column spacer BCS may be not spread out to the liquid crystal layer 300, thus preventing an afterimage on a screen. Furthermore, the barrier layer 160 is hydrophilic and an alignment layer 170 is hydrophilic, so that the alignment layer 170 may be easily coated on the barrier layer 160. Thus, the alignment layer 170 may be uniformly coated on the blocking part B of the black column spacer BCS.

The barrier layer 160 may include an inorganic insulating material. For example, the barrier layer 160 may include silicon nitride (SiNx) or silicon oxide (SiOx).

Alternatively, the barrier layer 160 may include a metal having a low reflectivity. For example, the barrier layer 160 may include chromium (Cr).

The substrate 210 may be a transparent insulation substrate. For example, the transparent insulation substrate may be a glass substrate, a plastic substrate or the like.

A common electrode CE may be formed on the substrate 210.

A grayscale voltage may be applied to the pixel electrode PE and the common electrode CE to form an electric field. For example, the common electrode CE may include a transparent conductive material, such as indium tin oxide (ITO), indium zinc oxide (IZO) and aluminum-doped zinc oxide (AZO). For example, the common electrode CE may have a slit pattern.

The alignment layer 170 may be formed on one surface of the substrate 110. For example, the alignment layer 170 may be formed on the passivation layer 150 and the barrier layer 160.

An alignment layer 220 may be formed on one surface of the substrate 210. For example, the alignment layer 220 may be formed on the common electrode CE.

The alignment layers 170 and 220 may pretilt liquid crystal molecules of the liquid crystal layer 300. The alignment layers 170 and 220 may be formed using an alignment liquid. For example, the alignment liquid may be a mixture of an aligning material such as polyimide PI and a solvent.

The alignment liquid is coated on the substrate 110 and the substrate 210, and then the solvent is dried, thus forming the alignment layers 170 and 220.

For example, the alignment liquid may be coated by a slit coating, a spin coating, or the like. The substrates 110 and 210 may be dried at a room temperature or heated to remove the solvent.

The liquid crystal layer 300 may be disposed between the substrate 110 and the substrate 210.

For example, the liquid crystal layer 300 may include liquid crystal molecules. An alignment of the liquid crystal molecules in the liquid crystal layer 300 may be controlled by an electric field applied between the pixel electrode PE and the common electrode CE. Therefore, a light transmittance of the pixel may be controlled.

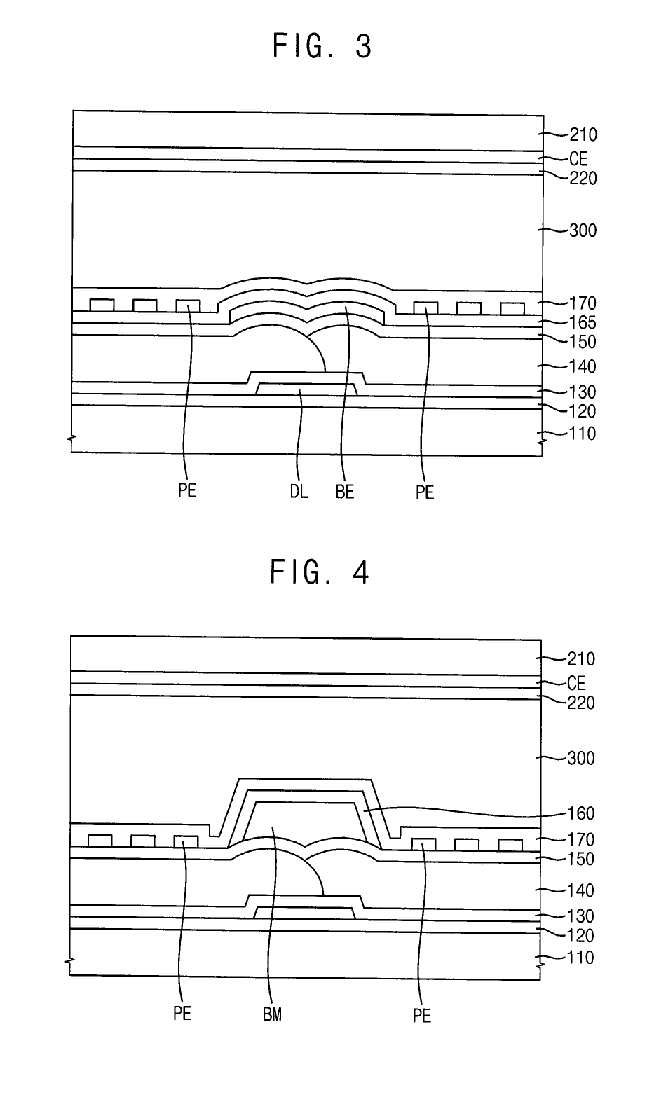

FIG. 3 is a cross-sectional view illustrating an exemplary embodiment of a display panel taken along the line I-I′ of FIG. 1.

Referring to FIGS. 1 to 3, the display panel may include a blocking electrode BE. The blocking electrode BE may be overlapped with the data line DL.

The blocking electrode BE may be disposed on the data line DL, a blocking signal may be applied to the blocking electrode BE. Thus, the liquid crystal molecules of the liquid crystal layer 300 overlapping with the blocking electrode BE may be vertically aligned, so that a screen may display a black image.

For example, the blocking electrode BE may include a transparent conductive material, such as indium tin oxide (ITO), indium zinc oxide (IZO) and aluminum-doped zinc oxide (AZO).

For example, the blocking electrode BE may be disposed between adjacent pixel electrodes PE. For example, the blocking electrode BE and the pixel electrode PE may be disposed on a different layer with each other.

A capping layer 165 may be disposed between the blocking electrode BE and the pixel electrode PE, and may insulate the blocking electrode BE.

FIG. 4 is a cross-sectional view illustrating another exemplary embodiment of a display panel taken along the line I-I′ of FIG. 1.

Referring to FIGS. 1, 2 and 4, the display panel includes a black matrix BM overlapping with the data line DL.

The black matrix BM may be disposed on the data line DL so that the black matrix BM may block light, which is reflected from the date line DL. Thus, a screen may display a black image.

For example, the black matrix BM may include a material substantially the same as that of the black column spacer BCS.

The black matrix BM may be disposed between adjacent pixel electrodes PE. For example, the black matrix BM and the pixel electrode PE may be disposed on a different layer with each other.

The barrier layer 160 may be disposed on an upper surface of the black matrix BM.

For example, the barrier layer 160 may cover the black matrix BM. Thus, the barrier layer 160 may prevent the black matrix BM from contacting with the liquid crystal layer 300.

Therefore, a component of the black matrix BM may be not spread out to the liquid crystal layer 300, thus preventing an afterimage on a screen.

The barrier layer 160 may include an inorganic insulating material. For example, the barrier layer 160 may include silicon nitride (SiNx) or silicon oxide (SiOx).

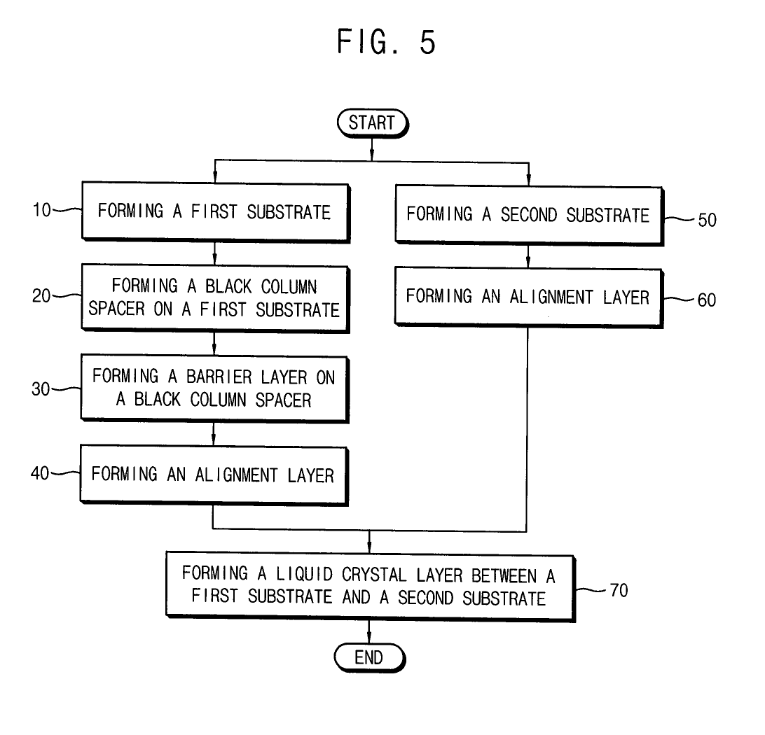

FIG. 5 is a flow chart illustrating an exemplary embodiment of a method for manufacturing a display panel.

Referring to FIGS. 1 to 5, the substrate 110 may be provided (10), and then a black column spacer BCS (20), a barrier layer 160 (30) and an alignment layer 170 may be formed on the substrate 110 (40). At the same time, the substrate 210 may be provided (50) and an alignment layer 220 may be formed on the substrate 210 (60). A liquid crystal layer is formed between the substrate layers 110 and 210 (70).

A gate line GL, a data line DL and a thin film transistor TFT may be formed on the substrate 110.

The gate line GL is extended in a direction D1, the data line DL is extended in a direction D2 crossing the direction D1. The thin film transistor TFT is connected to the gate line GL and the data line DL.

A color filter photoresist is coated on the thin film transistor TFT to form a color filter 140.

A pixel electrode PE is formed on the color filter 140.

The black column spacer BCS is formed on the substrate 110. For example, the black column spacer BCS may include a blocking part B and a maintaining part M.

The blocking part B covers the gate line GL and the thin film transistor TFT. The maintaining part M may be integrated with the blocking part B, the maintaining part may include a material substantially the same as that of the blocking part B.

A black photoresist is coated on the substrate 110.

The black photoresist may be a black material including a photosensitive organic material, a coloring agent and an initiator. The photosensitive organic material may polymerize or decompose by exposing light having a specific wavelength. For example, the black material includes a coloring agent such as a carbon black, an organic or inorganic pigment, a color mixed pigment or the like, thus representing a black color, thus displaying a black image.

The black photoresist may include at least two initiators having maximum energy absorption wavelengths different from each other.

The black photoresist may include a first initiator and a second initiator.

The first initiator may have a first maximum energy absorption wavelength reacting with a wavelength of a first light.

For example, the first initiator may have the maximum energy absorption wavelength within a range of about 300 nm to about 600 nm. For example, the first initiator may be titanocene-based initiator or acetophenone-based initiator.

The second initiator may have a second maximum energy absorption wavelength reacting with a wavelength of a second light.

For example, the second initiator may have the maximum energy absorption wavelength within a range of about 200 nm to about 300 nm. For example, the second initiator may be ester-based initiator, oxime-ester-based initiator, imidazole-based initiator or mercaptan-based initiator.

The black photoresist may be a negative-type photoresist.

The first light may be irradiated on the black photoresist, and then the black photoresist may be developed. A mask including a transparent area may be disposed on the black photoresist, and the transparent area may be disposed on an area forming the maintaining part M. The black photoresist may be polymerized and then hardened by irradiating the first light. A portion, which is not irradiated by the first light, may be developed, so that the portion may be removed.

The second light may be irradiated on the black photoresist. An amount of the second light may be smaller than an amount of the first light. A side surface of the blocking part B and the maintaining part M may have a tapered angle. The tapered angle may be controlled by the amount of the second light.

The black photoresist may be heated and dried, thereby forming the black column spacer. When the black photoresist is not radiated by the second light, the black photoresist may reflow by heating. Thus, a boarder between the second column spacer and the black matrix BM may be blurred, so that the black column spacer may not have a double stepped height.

Alternatively, a black photoresist may be coated on a color filter, and then the black photoresist may be irradiated once through a mask. The black photoresist may be developed and hardened, so that the black column spacer having the double stepped height may be formed. The mask may include a first area transmitting light, a blocking filter area transmitting a first light having a specific wavelength from an exposure and blocking a second light having another wavelength and a blocking area blocking light.

A barrier material may be deposited on the substrate 110, thereby forming a barrier layer 170 covering the blocking part B of the black column spacer BCS.

A barrier material may be deposited on one surface of the substrate 110. And then, the barrier material may be exposed to light using a mask having a desired pattern. Thus, a portion of the barrier material may be etched so that the barrier layer 170 may be patterned.

The barrier material may include an inorganic insulating material. For example, the barrier material may include silicon nitride (SiNx) or silicon oxide (SiOx).

Alternatively, the barrier material may include a metal having a low reflectivity. For example, the barrier material may include chromium (Cr).

An alignment layer 170 may be formed on one surface of the substrate 110.

The alignment layer 170 may be formed using an alignment liquid. For example, the alignment liquid may be a mixture of an aligning material such as polyimide PI and a solvent.

The alignment liquid is coated on the substrate 110, and then the solvent is dried, thus forming the alignment layers 170.

For example, the alignment liquid may be coated by a slit coating, a spin coating, or the like. The substrate 110 may be dried at a room temperature or heated to remove the solvent.

A common electrode CE is formed on the substrate 210. An alignment layer 220 may be formed on one surface of the substrate 210.

The substrate 110 and the substrate 210 may be disposed to face with each other, and then, a liquid crystal may be injected between the substrate 110 and the substrate 210 thereby forming a liquid crystal layer 300.

For example, a display panel may include a blocking electrode BE overlapping with the data line DL. The blocking electrode BE may be disposed on the data line DL, a blocking signal may be applied to the blocking electrode BE. Thus, the liquid crystal molecules of the liquid crystal layer 300 overlapping with the blocking electrode BE may be vertically aligned, so that a screen may display a black image. For example, the blocking electrode BE may include a transparent conductive material, such as indium tin oxide (ITO), indium zinc oxide (IZO) and aluminum-doped zinc oxide (AZO). A capping layer 165 may be disposed between the blocking electrode BE and the pixel electrode PE, and may insulate the blocking electrode BE.

Alternatively, a display may include a black matrix BM overlapping with the data line DL. The black matrix BM may be disposed on the data line DL so that the black matrix BM may block light, which is reflected from the date line DL. Thus, a screen may display a black image. For example, the black matrix BM may include a material substantially the same as that of the black column spacer A . The barrier layer 160 may be disposed on an upper surface of the black matrix BM.

According to an exemplary embodiment, a thin-film transistor substrate and a display panel may be used for a liquid crystal display apparatus, an organic light emitting apparatus or the like.

The foregoing is illustrative of the inventive concept and is not to be construed as limiting thereof. Although a few exemplary embodiments of the inventive concept have been described, those skilled in the art will readily appreciate that many modifications are possible in the exemplary embodiments without materially departing from the novel teachings and advantages of the inventive concept. Accordingly, all such modifications are intended to be included within the scope of the inventive concept as defined in the claims. Therefore, it is to be understood that the foregoing is illustrative of the inventive concept and is not to be construed as limited to the specific exemplary embodiments disclosed, and that modifications to the disclosed exemplary embodiments, as well as other exemplary embodiments, are intended to be included within the scope of the appended claims. The inventive concept is defined by the following claims, with equivalents of the claims to be included therein.

What is claimed is:

1. A display panel comprising:
a first substrate comprising a gate line extending in a first direction and a data line extending in a second direction crossing the first direction;
a second substrate facing the first substrate;
a thin film transistor disposed on the first substrate, and connected to the gate line and the data line;
a black column spacer including a blocking part covering the gate line and the thin film transistor to prevent light from being proved to the gate line and the thin film transistor, and a maintaining part integrated with the blocking part to maintain a cell gap between the first substrate and the second substrate, the maintaining part comprising a material substantially the same as that of the blocking part; and
a barrier layer covering the blocking part.

2. The display panel of claim 1, wherein the barrier layer comprises silicon nitride (SiNx) or silicon oxide (SiOx).

3. The display panel of claim 1, wherein the barrier layer comprises chromium (Cr).

4. The display panel of claim 1, wherein the maintaining part has a height of about 0.5 μm to about 3.0 μm.

5. The display panel of claim 1, further comprising:
a blocking electrode overlapping with the data line.

6. The display panel of claim 1, further comprising:
a black matrix overlapping with the data line.

7. The display panel of claim 6, wherein the black matrix comprises a material substantially the same as that of the black column spacer.

8. The display panel of claim 6, wherein the barrier layer further covers the black matrix.

9. The display panel of claim 1, further comprising:
an alignment layer disposed on at least one selected from the first substrate and the second substrate.

10. The display panel of claim 1, further comprising:
a liquid crystal layer disposed between the first substrate and the second substrate.

11. A method for manufacturing a display panel having a first substrate and a second substrate facing the first substrate, the method comprising:
forming a thin film transistor on the first substrate comprising a gate line extending in a first direction and a data line extending in a second direction crossing the first direction, the thin film transistor connected to the gate line and the data line;
forming a black column spacer on the first substrate, the black column spacer including:
a blocking part covering the gate line and the thin film transistor to prevent light from being proved to the gate line and the thin film transistor; and
a maintaining part integrated with the blocking part to maintain a cell gap between the first substrate and the second substrate, the maintaining part comprising a material substantially the same as that of the blocking part; and
depositing a barrier material on the first substrate to form a barrier layer covering the blocking part of the black column spacer.

12. The method of claim 11, further comprising:
forming a respective alignment layer on each of the first substrate and the second substrate; and
forming a liquid crystal layer between the first substrate and the second substrate.

13. The method of claim 11, wherein the barrier material comprises silicon nitride (SiNx) or silicon oxide (SiOx).

14. The method of claim 11, wherein the barrier material comprises chromium (Cr).

15. The method of claim 11, wherein forming the barrier layer comprises:
depositing the barrier material on one surface of the first substrate; and
exposing, using a mask, a portion of the barrier material to pattern the barrier layer.

16. The method of claim 11, further comprising:
coating a color filter photoresist on the thin film transistor to form a color filter; and
forming a pixel electrode on the color filter.

17. The method of claim 11, further comprising:
forming a blocking electrode overlapping with the data line.

18. The method of claim 11, further comprising:
forming a black matrix overlapping with the data line.

19. The method of claim 11, wherein forming the black column spacer comprises:
coating a black photoresist on the first substrate;
irradiating a first light to the black photoresist;
developing the black column spacer;
irradiating a second light to the black photoresist, an amount of the second light being smaller than an amount of the first light; and
drying the black photoresist by heating.

20. The method of claim 19, wherein the black photoresist comprises:
a first initiator having a first maximum energy absorption wavelength reacting with a wavelength of the first light, and
a second initiator having a second maximum energy absorption wavelength reacting with a wavelength of the second light.
